(19) United States
(12) Patent Application Publication
(10) Pub. No.: US 2012/0285506 A1
(43) Pub. Date: Nov. 15, 2012

(54) Solar Tracker

(76) Inventor: Chieh-Hsing Kuo, Kuan Shan Hsiang (TW)

(21) Appl. No.: 13/106,898

(22) Filed: May 13, 2011

(51) Int. Cl. H01L 31/052

(52) U.S. Cl. 136/246

(57) ABSTRACT

A solar tracker includes a main frame, pivotal first and second frames to both sides of the main frame respectively, solar panels on the frames, a vertical axle under the main frame, two hydraulic cylinders each having one end pivotably secured to the vertical axle and the other end secured to the bottom of the first or second frame, a support comprising two spaced inclined members pivotably secured to the bottom of the main frame, an extension board on an intermediate portion of the vertical axle, the bottom of the support being pivotably connected to the vertical axle, a telescopic actuating member secured to the extension board and engaged with the bottom of the main frame proximate to an edge of the main frame, a rotational seat rotatably secured to the vertical axle, and a vertical moving device comprising a platform for supporting the rotational seat.

### BACKGROUND OF THE INVENTION

1. Field of the Invention

The invention relates to solar energy and more particularly to a solar tracker with improved characteristics including being mobile, stowed, height adjustable, and adapted to freely rotate.

2. Description of Related Art

Climate change concerns, coupled with high oil prices, peak oil, and increasing government support, are driving increasing renewable energy legislation, incentives and commercialization. Solar energy as a mainstream form of renewable energy has been greatly utilized throughout the world in recent decades.

Solar cells (or photovoltaic cells) have the ability to convert sunlight directly into electricity. In order to capture the maximum amount of sunlight during the day, a tracker is connected to the cells and continuously aligns the light-absorbing panels of the cells in a direction perpendicular to rays from the sun so that the cells can absorb the highest amount of energy from the rays of sunlight.

A wide variety of solar trackers have been invented and some of them are commercially available. However, a number of drawbacks have been found in current solar trackers. For example, they are fixed to the ground or a building rather than mobile. Further, they are easy to stow. It is typical that a great space is occupied by a solar tracker. Moreover, there is no disclosure of a solar tracker capable of elevating and lowering, folding and unfolding, freely rotating, and being mobile. Thus, the need for improvement still exists.

### SUMMARY OF THE INVENTION

It is therefore one object of the invention to provide a solar tracker comprising a rectangular main frame, a rectangular first frame pivotably secured to one side of the main frame, and a rectangular second frame pivotably secured to the other side of the main frame wherein each of the first and second frames comprises a support rod disposed transversely; a plurality of solar cells mounted on top surfaces of the main frame, the first frame, and the second frame respectively; a vertical axle disposed under the main frame; two hydraulic cylinders each having one end pivotably secured to the vertical axle and the other end secured to the bottom of the first frame or the second frame; a support comprising two spaced inclined member pivotably secured to the bottom of the main frame, an extension board on an intermediate portion of the vertical axle under the main frame, the bottom of the support being pivotably connected to the vertical axle; a telescopic actuating member secured to the extension board and having an end engaged with the bottom of the main frame proximate to an edge of the main frame; a rotational seat rotatably secured to the vertical axle; and a vertical moving device comprising a rectangular platform for fastening and supporting the rotational seat thereon; wherein the support rods, the points of the inclined members pivotably secured to the main frame, and the other ends of the hydraulic cylinders are aligned; and wherein an activation of the telescopic actuating member is adapted to change an angle of the main frame with respect to the platform.

The above and other objects, features and advantages of the invention will become apparent from the following detailed description taken with the accompanying drawings.

### BRIEF DESCRIPTION OF THE DRAWINGS

FIG. 1 is a perspective view of a solar tracker according to the invention mounted on a flat bed of a flatbed truck;

FIG. 2 is a perspective view of a solar tracker according to a preferred embodiment of the invention;

FIG. 3 is a perspective view the solar tracker of FIG. 2 mounted on a vertical moving device and being lifted;

FIG. 4 is a perspective view of the solar tracker of FIG. 3 being lowered;

FIG. 5 is a view similar to FIG. 3 with the solar tracker being extended;

FIG. 6 is a perspective view of the solar tracker of FIG. 5 being folded downward;

FIG. 7 is a perspective view of the solar tracker of FIG. 5 being rotated clockwise at an inclined angle with respect to the base of the vertical moving device and in slope adjustment;

FIG. 8 is an elevational view of the solar tracker of FIG. 3 showing different orientations of the solar panel for absorbing the highest amount of energy from the rays of sunlight during the day; and

FIG. 9 is an exploded view of the vertical movement driver.

### DETAILED DESCRIPTION OF THE INVENTION

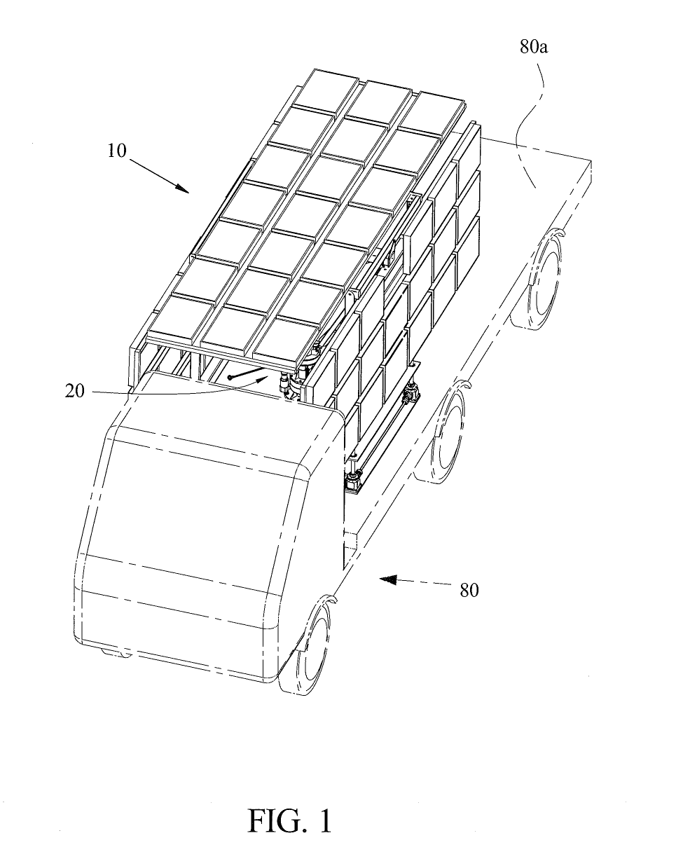

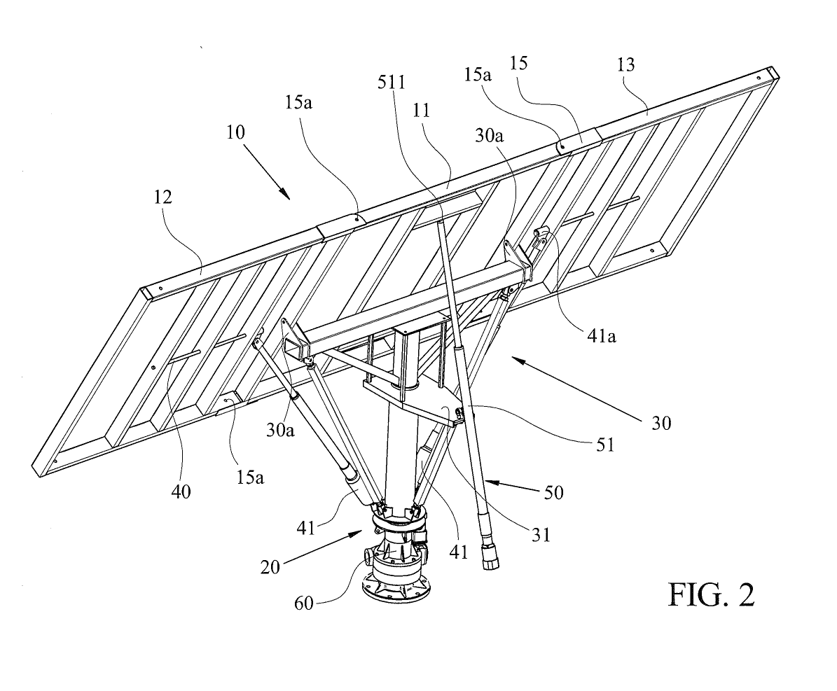

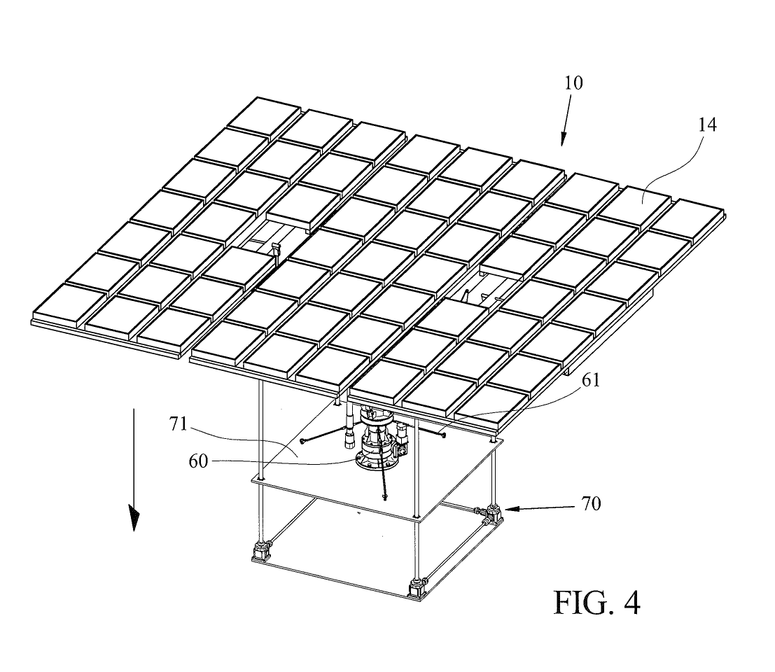

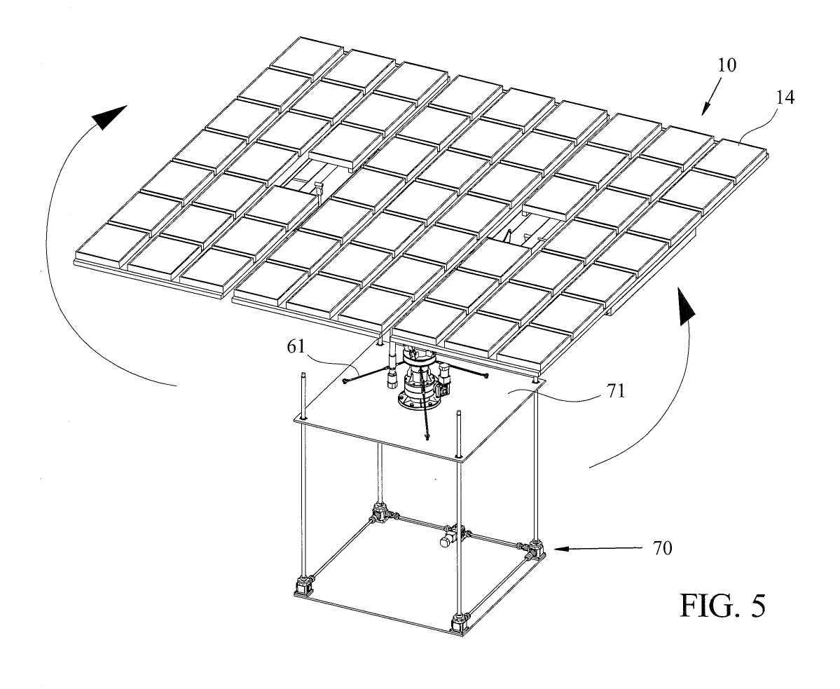

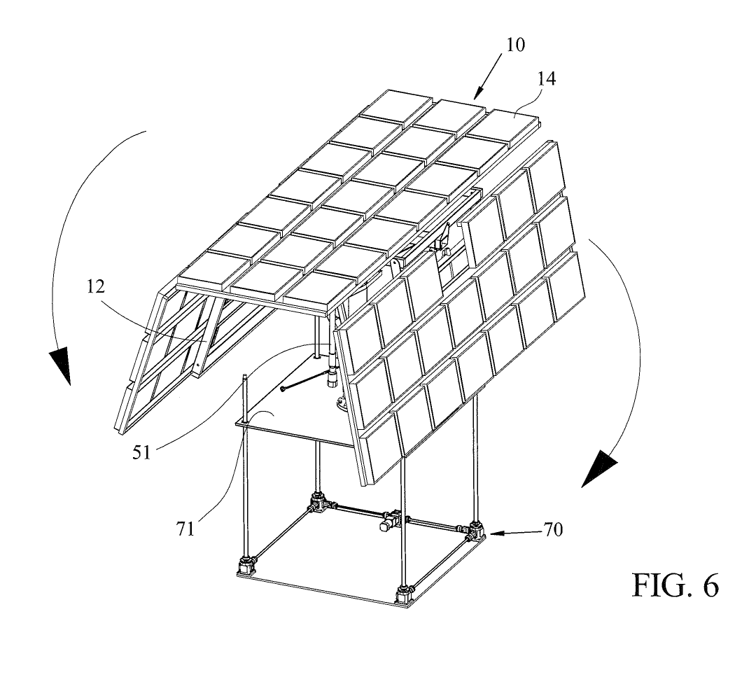

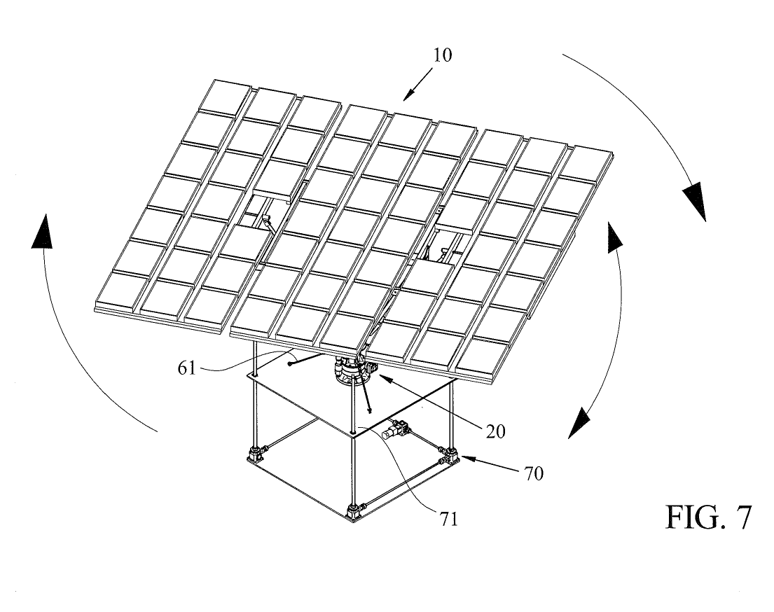

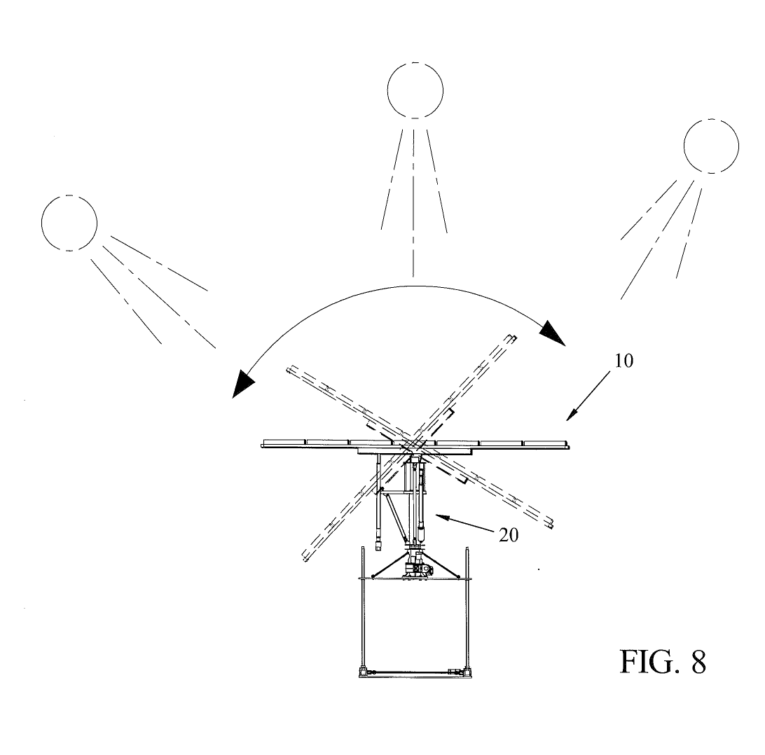

Referring to FIGS. 1 to 9, a solar tracker 10 in accordance with a preferred embodiment of the invention comprises the following components as discussed in detail below.

A rectangular intermediate main frame 11, a rectangular first frame 12 at one side, and a rectangular second frame 13 on the other side together form the shape of a rectangle. A plurality of rectangular solar cells 14 are mounted on top surfaces of the main frame 11, the first frame 12 and the second frame 13 to form three solar panels thereon respectively. Two sets of two U-shaped pivots 15 are provided. The pivot 15 has a pivot point 15a for pivotably joining top/bottom edges of the main frame 11 and the first frame 12 (or top/bottom edges of the main frame 11 and the second frame 13) together. Two opposite hydraulic cylinders 41 are provided in which one hydraulic cylinder 41 has one end pivotably secured to the bottom end of a vertical axle 20 and the other end 41a pivotably secured to an intermediate point at one side of the first frame 12 proximate the main frame 11, and the other hydraulic cylinder 41 has one end pivotably secured to the bottom end of the vertical axle 20 and the other end 41 a pivotably secured to an intermediate point at one side of the second frame 13 proximate the main frame 11. Each of the first and second frames 12, 13 is adapted to pivot with respect to the main frame 11 when the hydraulic cylinder 41 activates (i.e., extends or retracts).

A support 30 comprises two spaced inclined members 30a pivotably secured to the bottom of the main frame 11 respectively. The bottom of the support 30 is pivotably connected to the vertical axle 20 and further comprises an extension board 31 on an intermediate portion of the vertical axle 20 under the main frame 11. The top end of the vertical axle 20 is engaged with the bottom of the main frame 11. A telescopic actuating member 50 comprises a hydraulic cylinder 51 having an intermediate point secured to the extension board 31. Top end 511 of the actuating member 50 is secured to the bottom of the main frame 11 proximate to top edge thereof. The points of the inclined members 30a pivotably secured to the main frame 11 are aligned with the other ends 41a of the hydraulic cylinders 41. Thus, the solar tracker 10 may continuously align the light-absorbing solar panels in a direction perpendicular to rays from the sun. A back or forth movement of the hydraulic cylinder 51 may change the steepness of the slope of the solar tracker 10 (i.e., the frames 11, 12 and 13) so that the solar tracker 10 may continuously position the solar panels (i.e., the solar cells 14) relative to the position of the sun.

The solar tracker 10 is pivotably mounted on the vertical axle 20 and together they can be mounted on a flat bed 80a of a flatbed truck 80. Thus, the solar tracker 10 can be disposed at any desired location for light-absorbing purpose.

A vertical moving device 70 comprises a platform 71. A plurality of guy ropes 61 have one ends secured to the platform 71 and the other ends secured to the bottom end of the vertical axle 20 which is rotatably secured to a rotational seat 60. The main frame 11 may pivot forward or backward a predetermined angle to change the steepness of its slope. Also, the support 30 and thus the main frame 11 may pivot with respect to the vertical axle 20 (i.e., the rotational seat 60). Two opposite support rods 40 are disposed transversely through central portions of the first frame 12 and the second frame 13 respectively. The support rods 40, the other ends 41a of the hydraulic cylinders 41, and the points of the inclined members 30a pivotably secured to the main frame 11 are aligned.

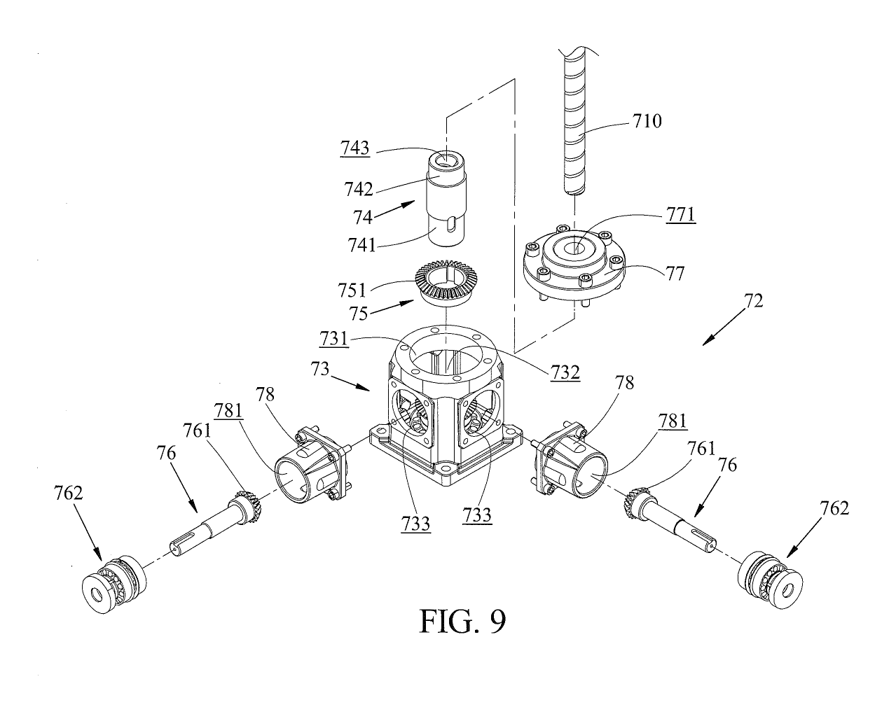

The rectangular platform 71 has four corners threadedly put on four screws 710 respectively. As shown in FIG. 9, a vertical movement driver 72 is provided on a bottom end of each screw 710. The vertical movement driver 72 comprises a hollow seat 73 of rectangular section, the seat 73 including a circular top opening 731, an internal space 732 communicating with the top opening 731, and two adjacent side openings 733 communicating with the space 732; a main gear 75 mounted on the blind bottom of the seat 73; two connecting shafts 76; and two hollow mounts 78 threadedly mounted on the side openings 733 respectively, each mount 78 including a cylindrical channel 781.

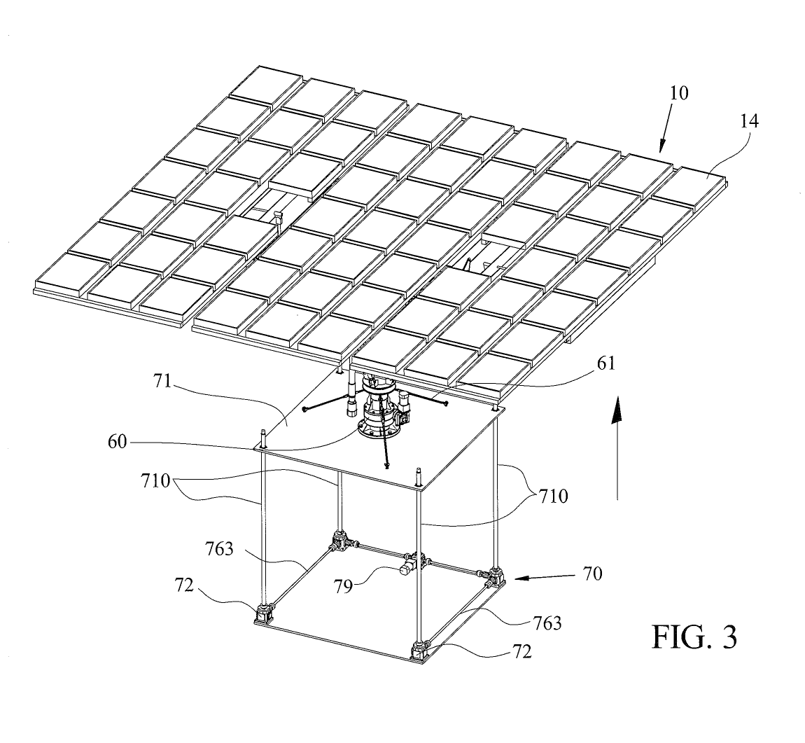

As shown in FIGS. 3 and 9 specifically, there are three connecting shafts 76 arranged as the shape of “]”. Each of the connecting shafts 76 comprises has teeth 761 at one end disposed through the channel 781 and one side opening 733 to mesh with teeth 751 of the main gear 75, teeth 761 at the other end (i.e., the teeth 761 of the other connecting shaft 76 shown in FIG. 9) disposed through the other channel 781 and the other side opening 733 to mesh with the teeth 751 of the main gear 75, two ball bearings 762 each disposed in the channel 781 and having an inner surface rotatably put on the connecting shaft 76 and an outer surface secured to a surface of the channel 781, and an interconnecting rod 763 having both ends each fixedly secured to a short rod-like extension of the teeth 761 proximate to the ball bearing 762.

The vertical movement driver 72 further comprises a sleeve 74 disposed in the space 732 of the seat 73 and including a through tunnel 743, a first end 741 secured to an inner surface of the main gear 75 so that they can be corotated, and a second end 742 opposite the first end 741, the second end 742 being secured to one end of the screw 710 so that the sleeve 74 and the screw 710 can be corotated; and a disk shaped cover 77 including a central hole 771 with the screw 710 freely passing through, the cover 77 threadedly secured to the top opening 731 for protecting components in the seat 73.

The vertical moving device 70 further comprises a motor (e.g., AC (alternating current) motor) 79 having a drive shaft operatively connected to one of the connecting shafts 76 so that an activation of the motor 79 can rotate the connecting shaft 76 which in turn lowers or lifts the platform 71 to an optimum elevation via the above gears and associated components. Further, the solar tracker 10 can be oriented to any desired angle by the rotation of the rotational seat 60. Furthermore, the steepness of the slope of the frames 11, 12 and 13 can be adjusted by the activation of the actuating member 50. As a result, the solar tracker 10 may continuously position the solar panels (i.e., the solar cells 14) relative to the position of the sun. In addition, the solar tracker 10 can be stowed by folding the first frame 12 and/or the second frame 13 when such need arises. Additionally, the solar tracker 10 can be mounted on a flat bed 80a of a flatbed truck 80, i.e., being mobile so as to dispose at any desired location for light-absorbing purpose.

While the invention has been described in terms of preferred embodiments, those skilled in the art will recognize that the invention can be practiced with modifications within the spirit and scope of the appended claims.

What is claimed is:

1. A solar tracker comprising:
a rectangular main frame, a rectangular first frame pivotably secured to one side of the main frame, and a rectangular second frame pivotably secured to the other side of the main frame wherein each of the first and second frames comprises a support rod disposed transversely;
a plurality of solar cells mounted on top surfaces of the main frame, the first frame, and the second frame respectively;
a vertical axle disposed under the main frame;
two hydraulic cylinders each having one end pivotably secured to the vertical axle and the other end secured to the bottom of the first frame or the second frame;
a support comprising two spaced inclined members pivotably secured to the bottom of the main frame, an extension board on an intermediate portion of the vertical axle under the main frame, the bottom of the support being pivotably connected to the vertical axle;
a telescopic actuating member secured to the extension board and having an end engaged with the bottom of the main frame proximate to an edge of the main frame;
a rotational seat rotatably secured to the vertical axle; and
a vertical moving device comprising a rectangular platform for fastening and supporting the rotational seat thereon;
wherein the support rods, the points of the inclined members pivotably secured to the main frame, and the other ends of the hydraulic cylinders are aligned; and
wherein an activation of the telescopic actuating member is adapted to change an angle of the main frame with respect to the platform.

2. The solar tracker of claim 1, further comprising a plurality of guy ropes each having one end secured to the platform and the other ends secured to the vertical axle.

3. The solar tracker of claim 1, wherein the vertical moving device is not fixed in one place.

4. The solar tracker of claim 1, wherein the vertical moving device comprises the platform, four screws threadedly disposed through four corners of the platform respectively, four hollow seats each comprising a top opening for allowing the screw to pass and dispose in the seat, and two adjacent side openings, four main gears each mounted in the seat, three connecting shafts each disposed through the opposite side openings of two adjacent seats and having both ends each meshed with the main gear, four sleeves each disposed in the seat to be securely put on a bottom end of the screw and secured to the main gear, and a drive member operatively connected to one of the connecting shafts so that an activation of the drive member is adapted to lower or lift the platform.
